(19) United States
(12) Patent Application Publication
(10) Pub. No.: US 2018/0151794 A1
(43) Pub. Date: May 31, 2018

(54) ELECTRONIC COMPONENT AND METHOD OF FABRICATING THE SAME

(71) Applicant: TAIYO YUDEN CO., LTD., Tokyo (JP)

(72) Inventor: Takuma KUROYANAGI, Tokyo (JP)

(73) Assignee: TAIYO YUDEN CO., LTD., Tokyo (JP)

(21) Appl. No.: 15/697,812

(22) Filed: Sep. 7, 2017

(30) Foreign Application Priority Data
Nov. 25, 2016 (JP) 2016-229474

(51) Int. Cl. H01L 41/047; H01L 41/25

(52) U.S. Cl. CPC H01L 41/0475; H01L 41/25

(57) ABSTRACT

An electronic component includes: a first substrate; a second substrate mounted on the first substrate so that a lower surface of the second substrate faces an upper surface of the first substrate across an air gap; a bump that bonds the upper surface of the first substrate and the lower surface of the second substrate and electrically connects the first substrate and the second substrate; a terminal located on the lower surface of the first substrate; and a via wiring that penetrates through the first substrate and at least a part of the bump and electrically connects the bump and the terminal.

### CROSS-REFERENCE TO RELATED APPLICATION

This application is based upon and claims the benefit of priority of the prior Japanese Patent Application No. 2016-229474, filed on Nov. 25, 2016, the entire contents of which are incorporated herein by reference.

### FIELD

A certain aspect of the present invention relates to an electronic component and a method of fabricating the same.

### BACKGROUND

A method that bonds substrates to each other so that the substrates face each other across an air gap by using bumps has been used to package electronic components such as acoustic wave devices. It has been known to provide a through electrode (a via wiring) that penetrates the substrate and is in contact with the bump as disclosed in, for example, Japanese Patent Application Publication Nos. 2007-305955 and 2002-305282.

When the bump size is reduced to reduce the size of the electronic component, the area of the bond with the substrate decreases. The decrease in the area of the bond with the substrate deteriorates the connection between the bump and the substrate.

### SUMMARY OF THE INVENTION

According to a first aspect of the present invention, there is provided an electronic component including: a first substrate; a second substrate mounted on the first substrate so that a lower surface of the second substrate faces an upper surface of the first substrate across an air gap; a bump that bonds the upper surface of the first substrate and the lower surface of the second substrate and electrically connects the first substrate and the second substrate; a terminal located on the lower surface of the first substrate; and a via wiring that penetrates through the first substrate and at least a part of the bump and electrically connects the bump and the terminal.

According to a second aspect of the present invention, there is provided a method of fabricating an electronic component, the method including: mounting a second substrate on a first substrate by using a bump so that a lower surface of the second substrate faces an upper surface of the first substrate across an air gap, the bump bonding the upper surface of the first substrate and the lower surface of the second substrate and electrically connecting the first substrate and the second substrate; forming a through hole that penetrates through the first substrate and at least a part of the bump after the mounting of the second substrate on the first substrate; forming a via wiring in the through hole; and forming, on the lower surface of the first substrate, a terminal electrically connected to the via wiring.

### BRIEF DESCRIPTION OF THE DRAWINGS

FIG. 1 is a cross-sectional view of an electronic component in accordance with a first comparative example;

FIG. 2A and FIG. 2B are cross-sectional views near a bump in the first comparative example;

FIG. 3A is a cross-sectional view of the electronic component in accordance with the first comparative example, and FIG. 3B is an enlarged view near the bump;

FIG. 4A and FIG. 4B are a cross-sectional view and a plan view of the electronic component in accordance with a first embodiment, respectively;

FIG. 5A and FIG. 5B are cross-sectional views illustrating examples of a functional element;

FIG. 6A is a cross-sectional view of the electronic component in accordance with the first embodiment, and FIG. 6B is a cross-sectional view near the bump;

FIG. 7 is a cross-sectional view of an electronic component in accordance with a first variation of the first embodiment;

FIG. 8 is a cross-sectional view of an electronic component in accordance with a second embodiment;

FIG. 9A through FIG. 9D are cross-sectional views (No. 1) illustrating a method of fabricating the electronic component in accordance with the second embodiment;

FIG. 10A through FIG. 10C are cross-sectional views (No. 2) illustrating the method of fabricating the electronic component in accordance with the second embodiment;

FIG. 11A through FIG. 11C are cross-sectional views (No. 3) illustrating the method of fabricating the electronic component in accordance with the second embodiment;

FIG. 12A through FIG. 12C are cross-sectional views (No. 4) illustrating the method of fabricating the electronic component in accordance with the second embodiment;

FIG. 13 is a cross-sectional view (No. 5) illustrating the method of fabricating the electronic component in accordance with the second embodiment; and

FIG. 14 is a cross-sectional view of an electronic component in accordance with a third embodiment.

### DETAILED DESCRIPTION

### First Comparative Example

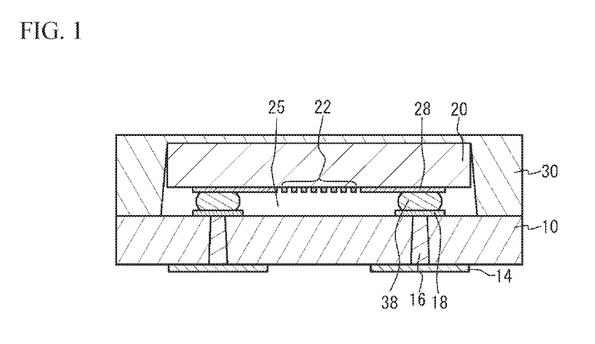

FIG. 1 is a cross-sectional view of an electronic component in accordance with a first comparative example. As illustrated in FIG. 1, a substrate 20 is mounted on the upper surface of a substrate 10. The substrate 10 is an insulating substrate, and is, for example, a ceramic substrate made of high temperature co-fired ceramic (HTCC) or low temperature co-fired ceramic (LTCC) or a resin substrate. Terminals 14 are located on the lower surface of the substrate 10, and terminals 18 are located on the upper surface of the substrate 10. The terminal 14 is an external terminal providing electrical connection with an external device, and is, for example, a foot pad. The terminal 18 is a pad to which a bump 38 is bonded. Via wirings 16 penetrating through the substrate 10 are formed. The via wiring 16 electrically connects the terminals 14 and 18. The terminals 14 and 18 and the via wirings 16 are metal layers such as a copper layer, a gold layer or an aluminum layer.

A functional element 22 and terminals 28 are located on the lower surface of the substrate 20. The terminal 28 is a pad to which the bump 38 is bonded. The functional element 22 is an acoustic wave element or the like. The terminals 28 and the functional element 22 are electrically connected. The substrate 20 is mounted on the substrate 10 through the bumps 38. A sealing portion 30 is located on the substrate 10 so as to cover the substrate 20. The sealing portion 30 is not formed between the substrates 10 and 20, and the functional element 22 faces the substrate 10 across an air gap 25. Since the functional element 22 is exposed to the air gap 25, the vibration of the functional element 22 is not restrained. The bumps 38 are, for example, copper bumps, gold bumps, or solder bumps. The sealing portion 30 is made of an insulating material such as resin or metal such as solder. The terminal 14 is electrically connected to the functional element 22 through the via wiring 16, the terminal 18, the bump 38, and the terminal 28.

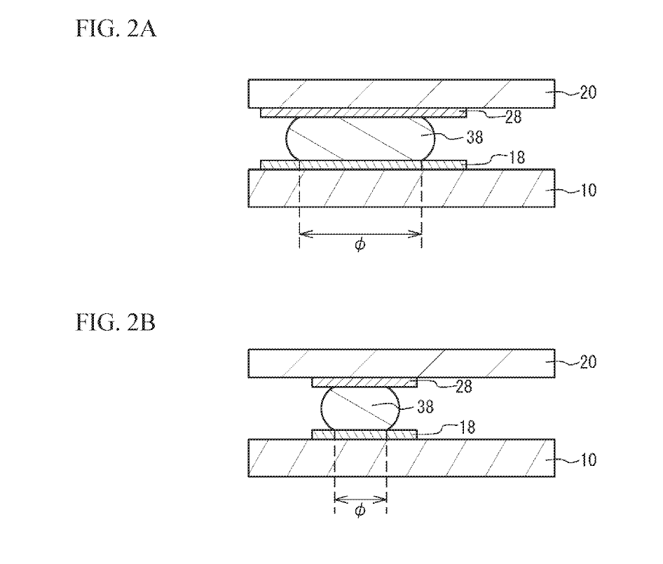

FIG. 2A and FIG. 2B are cross-sectional views near the bump in the first comparative example. As illustrated in FIG. 2A, when the diameter φ of the bump 38 is large, the area of contact between the bump 38 and the terminals 18 and 28 is large. Thus, the bond strength between the bump 38 and the terminals 18 and 28 is high.

As illustrated in FIG. 2B, when the diameter φ of the bump 38 is small, the area of contact between the bump 38 and the terminals 18 and 28 is small. Thus, the bond strength between the bump 38 and the terminals 18 and 28 is low.

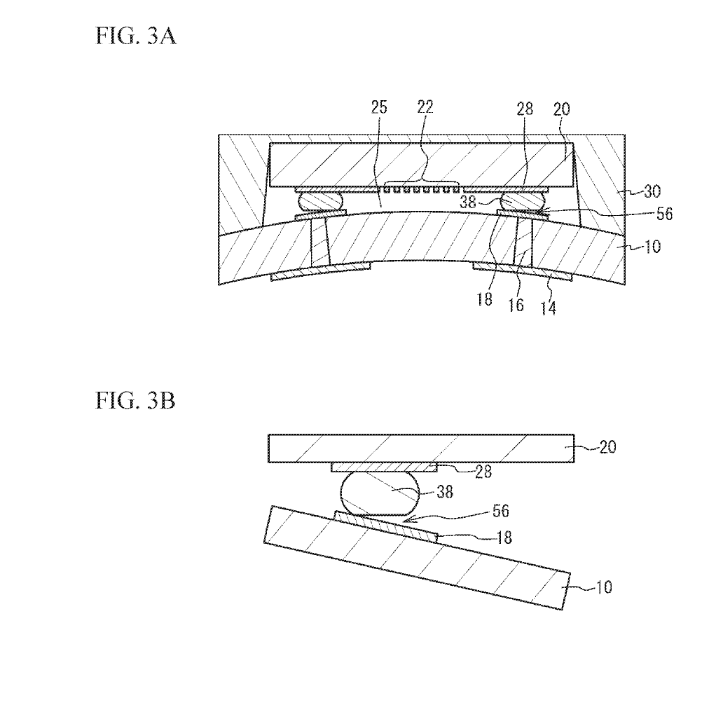

FIG. 3A is a cross-sectional view of the electronic component in accordance with the first comparative example, and FIG. 3B is an enlarged view near the bump. When the substrates 10 and 20 have different linear thermal expansion coefficients, the heat treatment to the electronic component may cause the substrate 10 and/or 20 to strain. Examples of the heat treatment to the electronic component include a reflow process for mounting the electronic component on a printed board. When the substrate 10 has a linear thermal expansion coefficient greater than that of the substrate 20, for example, the substrate 10 warps upward as illustrated in FIG. 3A. As illustrated in FIG. 3B, the stress concentrates around the bump 38, and peeling 56 of the bump 38 from the terminal 18 occurs. As described above, the connection between the bump 38 and the substrate 10 and/or 20 deteriorates. This may cut the electrical connection between the terminal 14 and the functional element 22.

### First Embodiment

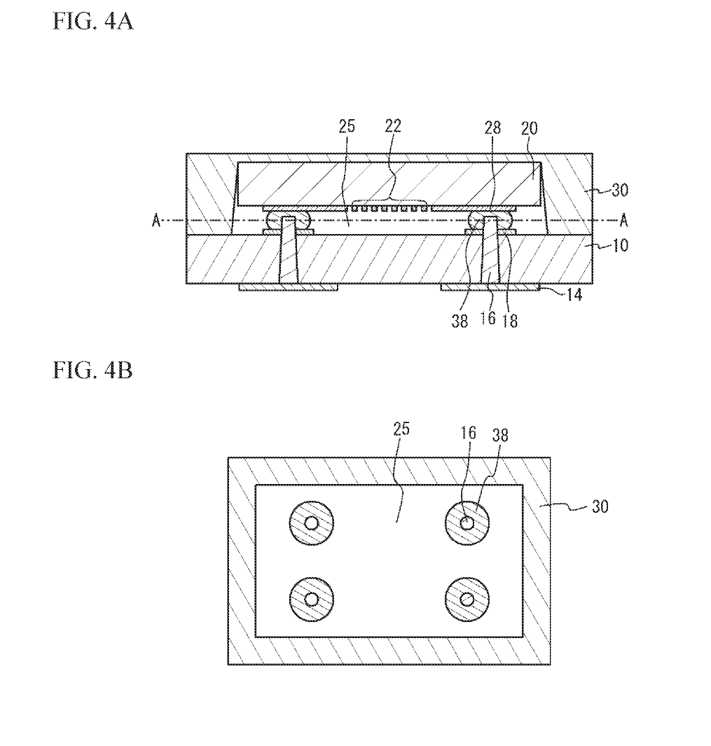

FIG. 4A and FIG. 4B are a cross-sectional view and a plan view of an electronic component in accordance with a first embodiment, respectively. FIG. 4B corresponds to the cross section taken along line A-A in FIG. 4A. As illustrated in FIG. 4A, the via wiring 16 penetrates through the terminal 18 and reaches the inside of the bump 38. As illustrated in FIG. 4B, the via wiring 16 is located inside the bump 38. The bump 38 is surrounded by the air gap 25. The sealing portion 30 surrounds the bumps 38 and the air gap 25.

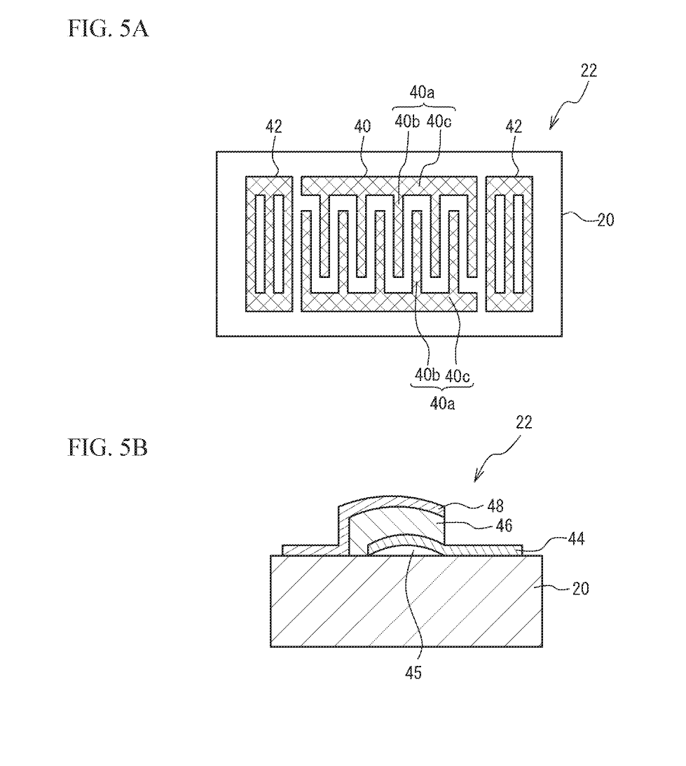

FIG. 5A and FIG. 5B are a plan view and a cross-sectional views illustrating examples of the functional element, respectively. As illustrated in FIG. 5A, the functional element 22 is a surface acoustic wave resonator. The substrate 20 is a piezoelectric substrate, and an interdigital transducer (IDT) 40 and reflectors 42 are formed on the substrate 20 (the lower surface in FIG. 4A, the same applies hereafter). The IDT 40 includes a pair of comb-shaped electrodes 40a facing each other. Each of the comb-shaped electrodes 40a includes a plurality of electrode fingers 40b and a bus bar 40c to which the electrode fingers 40b are coupled. The reflectors 42 are located at both sides of the IDT 40. The IDT 40 excites a surface acoustic wave on the substrate 20. The piezoelectric substrate is, for example, a lithium tantalate substrate or a lithium niobate substrate. The IDT 40 and the reflectors 42 are formed of, for example, an aluminum film or a copper film. The piezoelectric substrate may be bonded to the lower surface of a support substrate such as sapphire substrate, an alumina substrate, a spinel substrate, or a silicon substrate. A protective film or a temperature compensation film covering the IDT 40 and the reflectors 42 may be formed. In this case, the protective film or the temperature compensation film and the surface acoustic wave resonator function as the functional element 22 as a whole.

As illustrated in FIG. 5B, the functional element 22 is a piezoelectric thin film resonator. A piezoelectric film 46 is located on the substrate 20. A lower electrode 44 and an upper electrode 48 are located so as to sandwich the piezoelectric film 46. An air gap 45 is formed between the lower electrode 44 and the substrate 20. The lower electrode 44 and the upper electrode 48 excite the acoustic wave in the thickness extension mode inside the piezoelectric film 46. The lower electrode 44 and the upper electrode 48 are formed of, for example, a metal film such as a ruthenium film. The piezoelectric film 46 is, for example, an aluminum nitride film. The substrate 20 is an insulating substrate or a semiconductor substrate. As illustrated in FIG. 5A and FIG. 5B, the functional element 22 includes electrodes exciting the acoustic wave. Thus, the functional element 22 is covered with the air gap 25 so as not to restrain the acoustic wave. Other structures are the same as those of the first comparative example, and the description thereof is thus omitted.

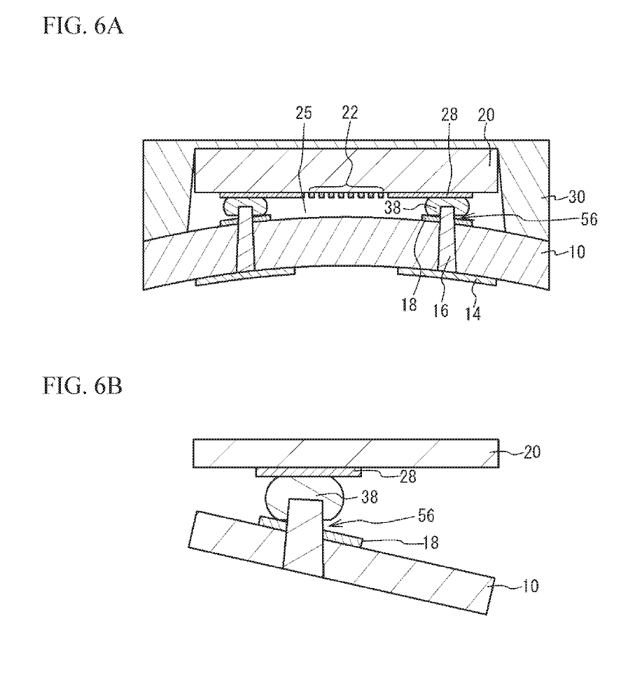

FIG. 6A is a cross-sectional view of the electronic component in accordance with the first embodiment, and FIG. 6B is a cross-sectional view near the bump. As illustrated in FIG. 6A, when the substrates 10 and 20 have different linear thermal expansion coefficients, the substrate 10 and/or 20 warps due to thermal stress as in the first comparative example. As illustrated in FIG. 6B, even when the peeling 56 of the bump 38 from the terminal 18 occurs, since the via wiring 16 is located inside the bump 38, the electrical connection between the via wiring 16 and the bump 38 is maintained. Additionally, since the via wiring 16 is located inside the bump 38 and the substrate 10, the warpage of the substrate 10 is reduced. Thus, the peeling of the bump 38 from the terminal 18 is inhibited. Therefore, the electrical connection between the terminal 14 and the functional element 22 is maintained.

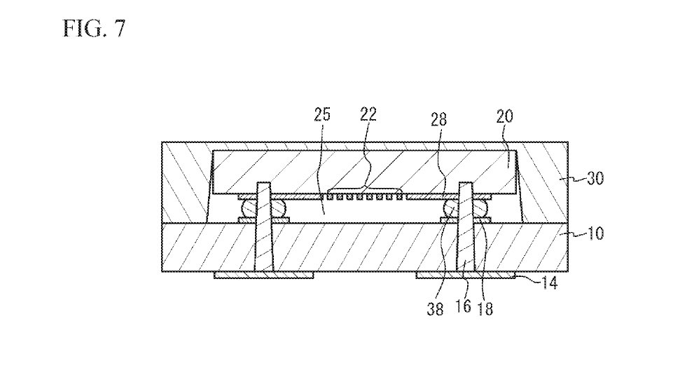

FIG. 7 is a cross-sectional view of an electronic component in accordance with a first variation of the first embodiment. As illustrated in FIG. 7, the via wiring 16 penetrates through the bump 38 and reaches the inside of the substrate 20. Other structures are the same as those of the first embodiment, and the description thereof is thus omitted.

Since the via wiring 16 penetrates through the bump 38 and reaches the inside of the substrate 20, even when the bump 38 peels from the terminal 28, the electrical connection between the bump 38 and the terminal 28 is maintained. In addition, the warpage of the substrate 10 and/or 20 is further reduced. Thus, the bump 38 is inhibited from peeling from the terminal 18 and/or 28.

In the first embodiment and the variation thereof, the substrate 20 (a second substrate) is mounted on the substrate 10 (a first substrate) so that the lower surface of the substrate 20 faces the upper surface of the substrate 10 across the air gap 25. The bump 38 bonds the upper surface of the substrate 10 and the lower surface of the substrate 20 together, and electrically connects the substrate 10 and the substrate 20. The via wiring 16 penetrates through the substrate 10 and at least a part of the bump 38, and electrically connects the bump 38 and the terminal 14. This structure reduces the deterioration of the electrical connection between the bump 38 and the substrate 10 and/or 20 even when the substrate 10 and/or 20 warps as illustrated in FIG. 6A and FIG. 6B.

The functional element 22 is located on the lower surface of the substrate 20 so as to face the upper surface of the substrate 10 across the air gap 25. Since the functional element 22 is exposed to the air gap 25, a member for reinforcing the bump 38 such as an underfill agent is not able to be provided. In such a case, the electrical connection between the bump 38 and the substrate 10 and/or 20 easily deteriorates. Thus, the via wiring 16 preferably penetrates at least a part of the bump 38.

Furthermore, the sealing portion 30 is bonded to the upper surface of the substrate 10, surrounds the substrate 20, and seals the air gap 25. Since the sealing portion 30 seals the air gap 25, the reinforcement of the bump 38 is impossible. In such a case, the electrical connection between the bump 38 and the substrate 10 and/or 20 easily deteriorates. Thus, the via wiring 16 preferably penetrates at least a part of the bump 38.

Furthermore, as illustrated in FIG. 4B, the bump 38 is surrounded by the air gap 25 in plan view. In such a case, the electrical connection between the bump 38 and the substrate 10 and/or 20 easily deteriorates. Thus, the via wiring 16 preferably penetrates at least a part of the bump 38.

As illustrated in FIG. 7, the via wiring 16 penetrates through the bump 38, and is in contact with the substrate 20. This structure further reduces the deterioration of the electrical connection between the bump 38 and the substrate 10 and/or 20.

### Second Embodiment

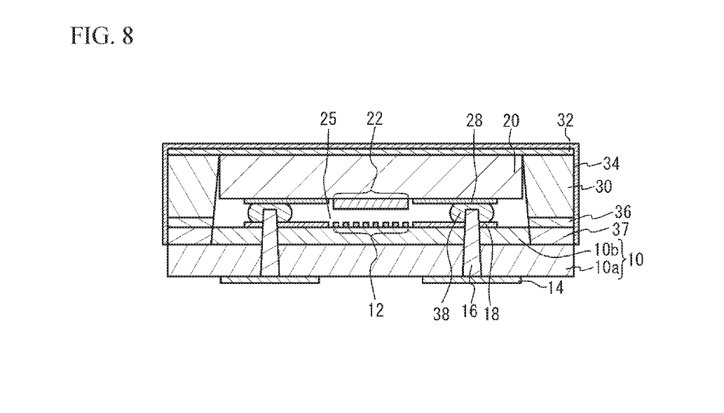

FIG. 8 is a cross-sectional view of an electronic component in accordance with a second embodiment. As illustrated in FIG. 8, the substrate 10 includes a support substrate 10a and a piezoelectric substrate 10b bonded on the support substrate 10a. A functional element 12 is located on the substrate 10. The terminal 18 is electrically connected to the functional element 12. The functional element 12 is the surface acoustic wave element illustrated in FIG. 5A. The piezoelectric substrate 10b is removed and a ring-shaped metal layer 37 is located so as to surround the terminals 18 in plan view. A ring-shaped electrode 36 is located on the ring-shaped metal layer 37. The functional element 22 located on the lower surface of the substrate 20 is the piezoelectric thin film resonator illustrated in FIG. 5B. The sealing portion 30 is located so as to surround the substrate 20 in plan view. The sealing portion 30 is a metal member made of solder or the like, and is bonded to the ring-shaped electrode 36. A lid 32 is located on the substrate 20 and the sealing portion 30. The lid 32 is a metal plate made of kovar or the like or a plate made of an insulating material. A protective film 34 is located so as to cover the ring-shaped metal layer 37, the ring-shaped electrode 36, the sealing portion 30, and the lid 32. The protective film 34 is a metal film or an insulating film. Other structures are the same as those of the first embodiment, and the description thereof is thus omitted.

### Fabrication Method of the Second Embodiment

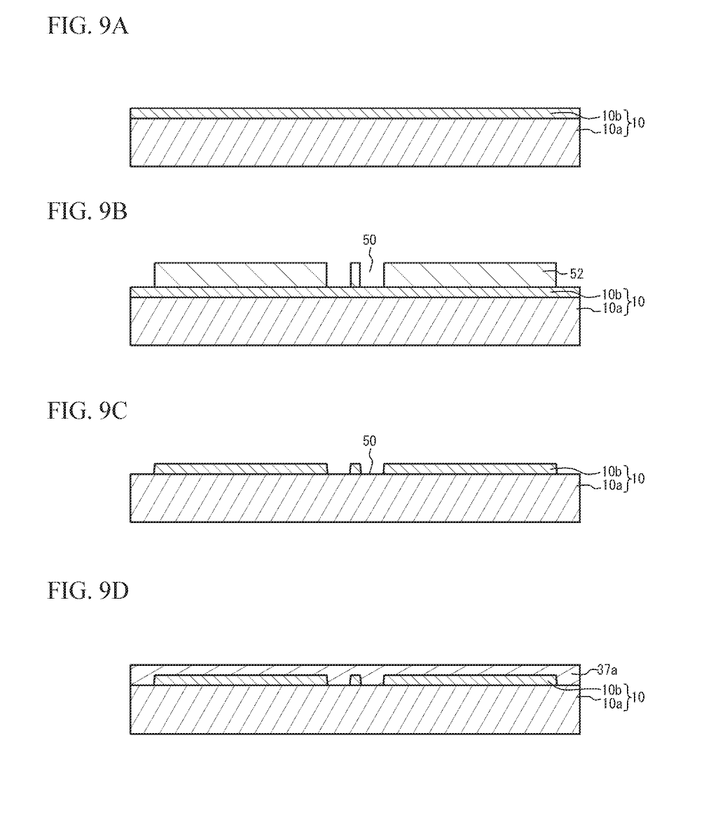

FIG. 9A through FIG. 13 are cross-sectional views illustrating a method of fabricating the electronic component in accordance with the second embodiment. As illustrated in FIG. 9A, the lower surface of the piezoelectric substrate 10b is bonded on the upper surface of the support substrate 10a. The support substrate 10a is, for example, a sapphire substrate, and the piezoelectric substrate 10b is, for example, a lithium tantalate substrate with a film thickness of 10 to 20 μm. The bonding is performed in a wafer state. Examples of the bonding method include a method that activates the upper surface of the support substrate 10a and the lower surface of the piezoelectric substrate 10b and then bonds them together at normal temperature, and a method that bonds the substrates with an adhesive agent.

As illustrated in FIG. 9B, a mask layer 52 made of a photoresist having apertures 50 is formed on the piezoelectric substrate 10b. As illustrated in FIG. 9C, the piezoelectric substrate 10b is removed using the mask layer 52 as a mask to form the apertures 50. The piezoelectric substrate 10b is removed by, for example, blasting, ion milling, or wet etching. Then, the mask layer 52 is peeled. As illustrated in FIG. 9D, a metal layer 37a to be the ring-shaped metal layer 37 is formed inside the apertures 50 and on the piezoelectric substrate 10b. The metal layer 37a is, for example, a copper layer. The metal layer 37a is formed as follows. For example, a seed layer (for example, a titanium layer with a film thickness of 100 μm and a copper layer with a film thickness of 200 μm) is formed on the substrate 10 by sputtering, and a plated layer is then formed on the seed layer.

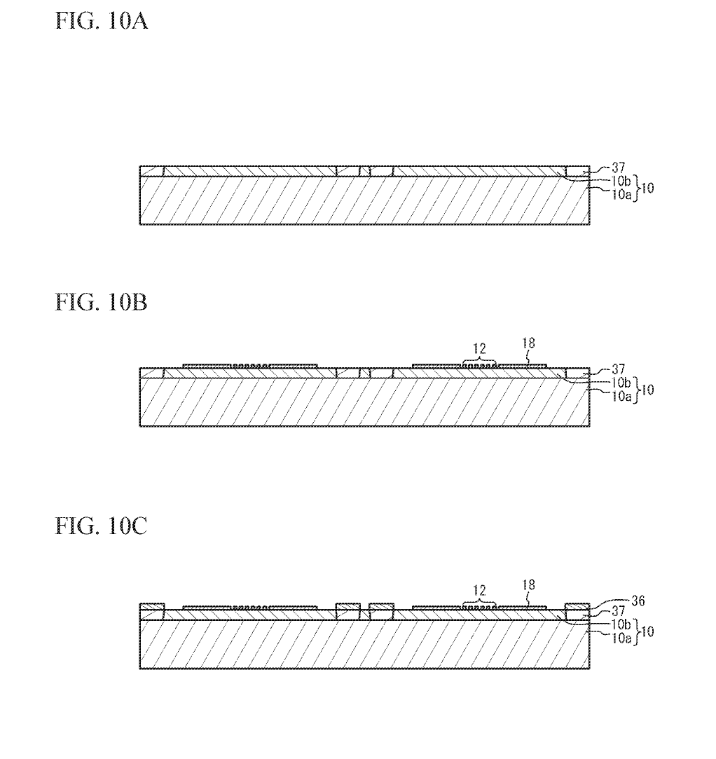

As illustrated in FIG. 10A, the metal layer 37a on the piezoelectric substrate 10b is removed. The metal layer 37a is removed by, for example, chemical mechanical polishing (CMP). This process embeds the ring-shaped metal layers 37 in the apertures 50. As illustrated in FIG. 10B, the functional elements 12 and the terminals 18 are formed on the upper surface of the piezoelectric substrate 10b. The functional elements 12 are formed of, for example, a titanium film and an aluminum film stacked in this order from the substrate 10 side. The terminal 18 has a film thickness of, for example, 2.5 μm, and is formed of, for example, a titanium film and a gold film stacked in this order from the substrate 10 side. As illustrated in FIG. 10C, the ring-shaped electrode 36 is formed on the ring-shaped metal layer 37. The ring-shaped electrode 36 is formed of, for example, a titanium film and a nickel film stacked in this order from the substrate 10 side, and is formed by evaporation and liftoff.

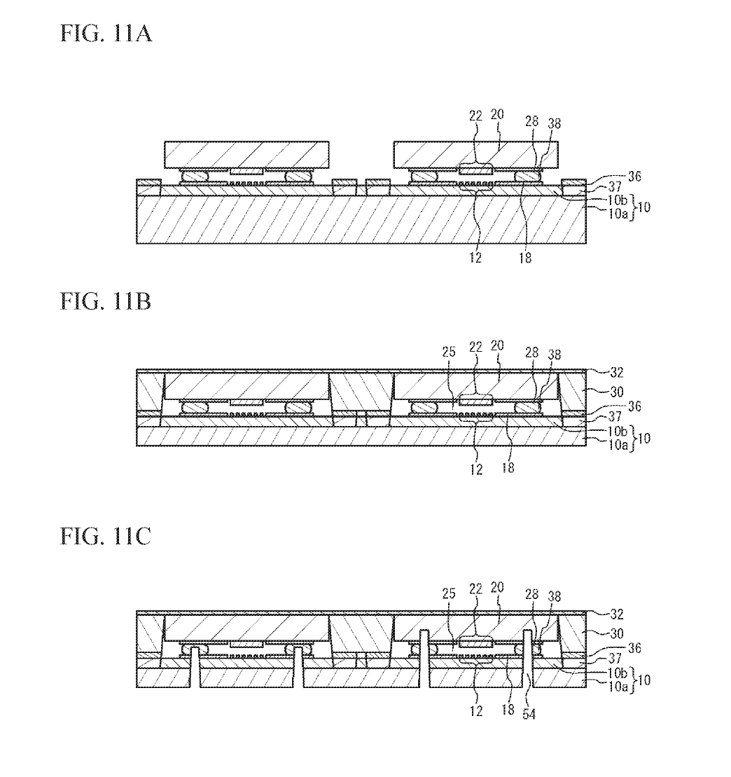

As illustrated in FIG. 11A, the substrates 20 are flip-chip mounted on the substrate 10. The substrates 20 are chips individually separated, and gold stud bumps as the bumps 38 are formed on the lower surface of the substrate 20. As illustrated in FIG. 11B, a solder plate is placed on the substrate 10 so as to cover the substrates 20. The lid 32 is placed on the solder plate. The solder plate is pressed against the substrate 10 with the lid 32, and is heated to a temperature greater than the melting point of the solder plate. For example, the melting point of SnAg solder is approximately 220° C. Thus, the solder plate is heated to a temperature equal to or greater than 230° C. This process melts the solder plate, thereby forming the sealing portion 30. The sealing portion 30 forms the ring-shaped electrode 36 and alloy. Thus, the sealing portion 30 bonds with the ring-shaped metal layer 37. Since the lid 32 has good solderability, the sealing portion 30 bonds with the lid 32. The lid 32 is in contact with the upper surface of the substrate 20, but does not bond with the upper surface of the substrate 20. The distance between the upper surface of the substrate 10 and the lower surface of the substrate 20 is, for example, 10 to 20 μm. Thereafter, the lower surface of the substrate 10 is polished to thin the substrate 10 to the film thickness of, for example, 100 to 150 μm.

As illustrated in FIG. 11C, the lower surface of the substrate 10 is irradiated with a laser beam to form through holes 54 penetrating through the substrate 10, the terminal 18, and a part of the bump 38. The laser beam is, for example, the third order harmonics of the YAG laser. The laser beam may be a carbon dioxide laser beam. The through hole 54 may not necessarily reach the terminal 28, or may reach the substrate 20. In the drawings hereinafter, a case where the through hole 54 reaches the substrate 20 is illustrated on the right side, and a case where the through hole 54 reaches only the inside of the bump 38 is illustrated on the left side. The upper surface of the through hole 54 has a diameter of, for example, 10 μm, and the lower surface of the through hole 54 has a diameter of, for example, 45 μm.

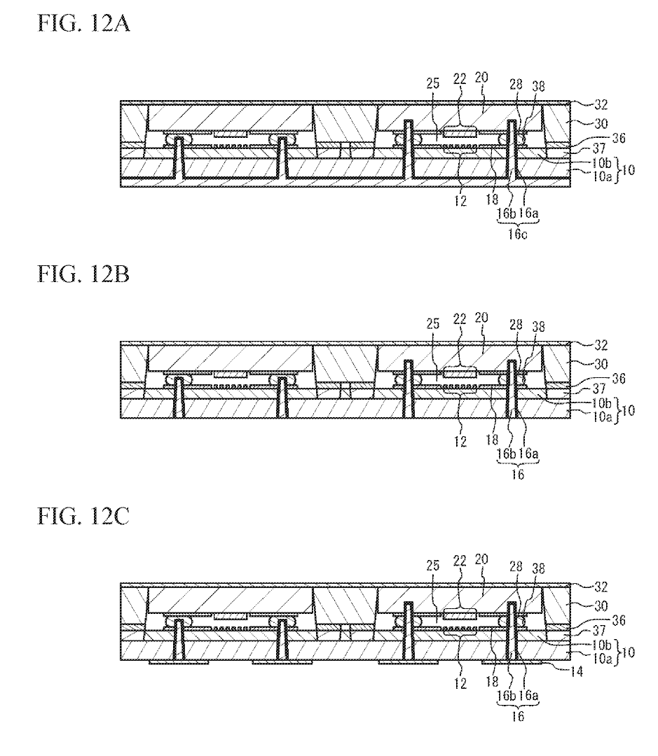

As illustrated in FIG. 12A, a metal layer 16c is formed inside the through holes 54 and under the substrate 10. The metal layer 16c is, for example, a copper layer. The metal layer 16c is formed as follows. For example, a seed layer 16a (for example, a titanium layer with a film thickness of 100 μm and a copper layer with a film thickness of 200 μm) is formed by sputtering, and then a plated layer 16b is formed under the seed layer 16a. As illustrated in FIG. 12B, the metal layer 16c under the support substrate 10a is removed. The metal layer 16c is removed by, for example, CMP. This process embeds the via wirings 16 inside the through holes 54. As illustrated in FIG. 12C, the terminals 14 being in contact with the via wirings 16 are formed on the lower surface of the support substrate 10a.

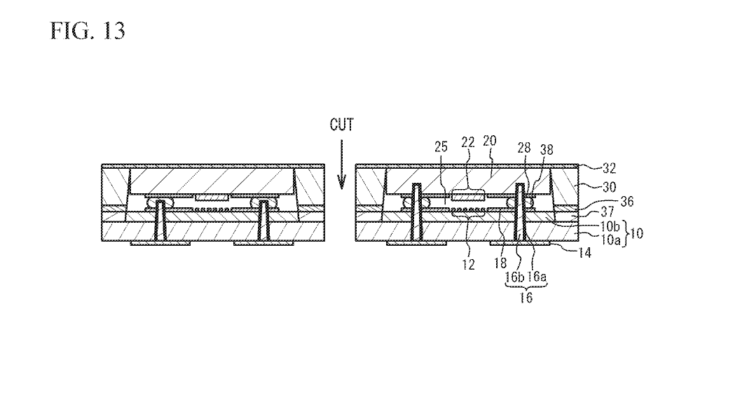

As illustrated in FIG. 13, the lid 32, the sealing portion 30, the substrate 10 are cut by, for example, dicing. This process separates individual electronic components. Then, the protective film 34 is formed on each of the cut electronic components. The protective film 34 is formed by, for example, barrel plating. The above processes complete the electronic component in accordance with the second embodiment.

In the second embodiment, as illustrated in FIG. 11A, after the substrate 20 is mounted on the substrate 10, the through hole 54 penetrating through the substrate 10 and at least a part of the bump 38 is formed as illustrated in FIG. 11C. As illustrated in FIG. 12B, the via wiring 16 is formed inside the through hole. These processes allow to form the via wiring 16 penetrating through the substrate 10 and located in at least a part of the bump 38.

As described in the second embodiment, the substrate 10 may include the support substrate 10a and the piezoelectric substrate 10b bonded on the support substrate 10a. A case where the functional element 12 located on the upper surface of the substrate 10 is a surface acoustic wave element and the functional element 22 located on the lower surface of the substrate 20 is a piezoelectric thin film resonator has been described. However, the functional element 12 on the substrate 10 may be a piezoelectric thin film resonator, and the functional element 22 on the substrate 20 may be a surface acoustic wave element. Both the functional elements 12 and 22 may be surface acoustic wave elements or piezoelectric thin film resonators.

The functional element 12 may form a filter, and the functional element 22 may form a filter. The functional elements 12 and 22 may form a multiplexer such as a duplexer.

### Third Embodiment

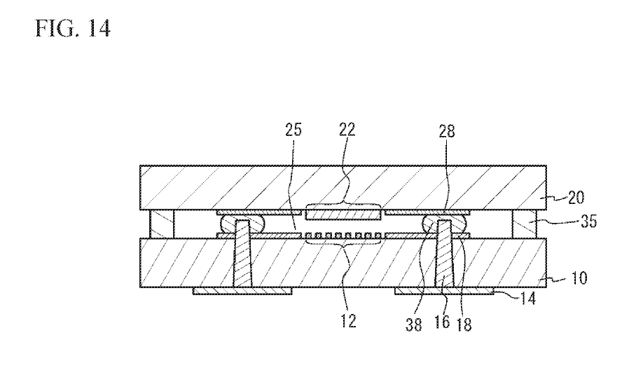

FIG. 14 is a cross-sectional view of an electronic component in accordance with a third embodiment. As illustrated in FIG. 14, the bumps 38 and a ring-shaped sealing portion 35 are located between the substrate 10 and the substrate 20. The ring-shaped sealing portion 35 is located in the peripheries of the substrates 10 and 20. The ring-shaped sealing portion 35 is formed of a metal layer such as a copper layer, a gold layer, or a solder layer. The functional element 12 is located on the upper surface of the substrate 10, and the functional element 22 is located on the lower surface of the substrate 20. Other structures are the same as those of the first embodiment, and the description thereof is thus omitted. As described in the third embodiment, the sealing portion may be located between the substrates 10 and 20.

In the first through third embodiments, the functional element 12 and/or 22 may be an active element such as an amplifier and/or a switch. Alternatively, the functional element 12 and/or 22 may be a passive element such as an inductor and/or a capacitor.

Although the embodiments of the present invention have been described in detail, it is to be understood that the various change, substitutions, and alterations could be made hereto without departing from the spirit and scope of the invention.

What is claimed is:

1. An electronic component comprising:
a first substrate;
a second substrate mounted on the first substrate so that a lower surface of the second substrate faces an upper surface of the first substrate across an air gap;
a bump that bonds the upper surface of the first substrate and the lower surface of the second substrate and electrically connects the first substrate and the second substrate;
a terminal located on the lower surface of the first substrate; and
a via wiring that penetrates through the first substrate and at least a part of the bump and electrically connects the bump and the terminal.

2. The electronic component according to claim 1, wherein
the bump is surrounded by the air gap in plan view.

3. The electronic component according to claim 1, further comprising
a functional element located on the lower surface of the second substrate so as to face the upper surface of the first substrate across the air gap.

4. The electronic component according to claim 3, further comprising
a sealing portion that bonds with the upper surface of the first substrate, surrounds the second substrate, and seals the air gap.

5. The electronic component according to claim 3, wherein
the functional element is an acoustic wave element.

6. The electronic component according to claim 1, wherein
the via wiring penetrates through the bump and is in contact with the second substrate.

7. The electronic component according to claim 1, wherein
the first substrate has a linear thermal expansion coefficient greater than a linear thermal expansion coefficient of the second substrate.

8. The electronic component according to claim 1, wherein
the first substrate includes a support substrate and a piezoelectric substrate bonded on the support substrate.

9. A method of fabricating an electronic component, the method comprising:
mounting a second substrate on a first substrate by using a bump so that a lower surface of the second substrate faces an upper surface of the first substrate across an air gap, the bump bonding the upper surface of the first substrate and the lower surface of the second substrate and electrically connecting the first substrate and the second substrate;
forming a through hole that penetrates through the first substrate and at least a part of the bump after the mounting of the second substrate on the first substrate;
forming a via wiring in the through hole; and
forming, on the lower surface of the first substrate, a terminal electrically connected to the via wiring.
